(19) United States
(12) Patent Application Publication
(10) Pub. No.: US 2024/0250021 A1
(43) Pub. Date: Jul. 25, 2024

(54) APPARATUS AND INTERNAL VOLTAGE GENERATING CIRCUIT INCLUDING VOLTAGE DIVIDING CIRCUIT

(71) Applicant: Micron Technology, Inc., Boise, ID (US)

(72) Inventors: KENICHI ECHIGOYA, Sagamihara (JP); HIDEKAZU EGAWA, Tokyo (JP)

(73) Assignee: Micron Technology, Inc., Boise, ID (US)

(21) Appl. No.: 18/521,490

(22) Filed: Nov. 28, 2023

Related U.S. Application Data
(60) Provisional application No. 63/481,472, filed on Jan. 25, 2023.

(51) Int. Cl. H01L 23/522; H01L 23/528; H10B 12/00

(52) U.S. Cl. CPC H01L 23/5228; H01L 23/5283; H10B 12/50

(57) ABSTRACT

According to one or more embodiments of the disclosure, an apparatus comprising a voltage dividing circuit is provided. The voltage dividing circuit includes a first resistor unit, a second resistor unit parallel to the first resistor unit in a first direction, and a bridge. The bridge is between the first resistor unit and the second resistor unit and links a first middle portion of the first resistor unit to a second middle portion of the second resistor unit. The first and second middle portions are middle portions of the first and the second resistor units in a second direction perpendicular to the first direction.

### CROSS REFERENCE TO RELATED APPLICATION(S)

This application claims priority to U.S. Provisional Application No. 63/481,472, filed Jan. 25, 2023. The aforementioned application is incorporated herein by reference, in its entirety, for any purpose.

### BACKGROUND

High data reliability, high speed of memory access, low power consumption, and reduced chip size are some features that are demanded from semiconductor memory devices. To achieve the further reduced chip size and the lower power consumption while maintaining or improving the data reliability and the memory access speed, there may be a wider variation of circuit component size and hence a greater number of internal voltages in a chip. To provide various internal voltages, an internal voltage generating circuit including a voltage dividing circuit may be provided.

### BRIEF DESCRIPTION OF THE DRAWINGS

FIG. 1 depicts a block diagram of an apparatus according to an embodiment of the disclosure.

FIG. 2 depicts an equivalent circuit of resistors and switches of a voltage dividing circuit according to an embodiment of the disclosure.

FIGS. 3A and 3B depict a schematic configuration of resistor units of a voltage dividing circuit in a perspective view and a plan view, respectively, according to an embodiment of the disclosure.

FIGS. 4A, 4B, and 4C depict a schematic configuration of resistor units of a voltage dividing circuit in a plan view according to an embodiment of the disclosure.

FIG. 5 depicts a schematic configuration of resistor units of a voltage dividing circuit in a plan view according to an embodiment of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, the dimensions and dimensional ratios of each unit do not necessarily match the actual dimensions and dimensional ratios in the embodiments.

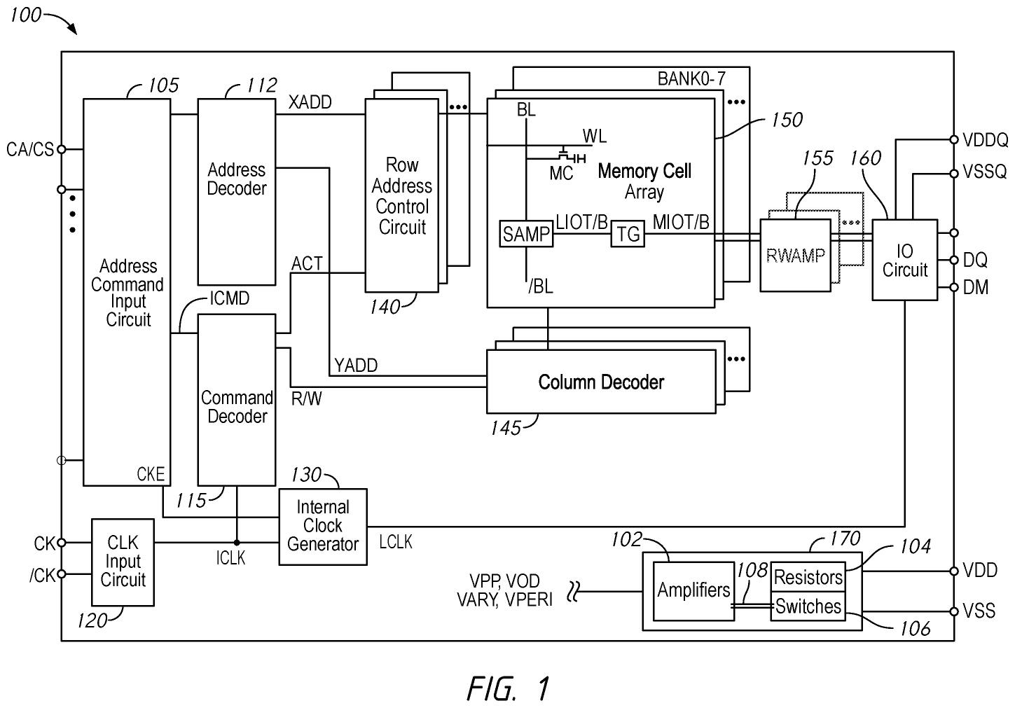

FIG. 1 depicts an example of a block diagram of an apparatus 100 according to an embodiment of the disclosure. The apparatus 100 may be a semiconductor device. The semiconductor device may include a memory device. One example of a memory device is a dynamic random access memory (DRAM). A memory device may be capable of storing data in a plurality of memory cells. A memory device may have reduced chip size, increased access speed, and decreased power consumption.

In the case of a memory device, the apparatus 100 includes a memory array (may also be referred to as a memory cell array) 150. The memory array 150 includes a plurality of memory banks, for example BANK0-7. Each bank includes a plurality of word lines WL, a plurality of bit lines BL, and a plurality of memory cells. The memory cells are arranged at intersections of the word lines WL and the bit lines BL. A plurality of sense amplifiers SAMP are provided for the corresponding bit lines BL. Each sense amplifier SAMP is connected to at least one local I/O line pair LIOT/B. The local I/O line pair LIOT/B is coupled to at least one main I/O line pair MIOT/B via one or more transfer gates TG. The transfer gates TG function as switches.

The apparatus 100 is provided with a plurality of external terminals. The external terminals include, but are not limited to, command and address and chip select (CA/CS) terminals, clock terminals CK and/CK, data terminals DQ and DM, and power supply terminals VDD, VSS, VDDQ, and VSSQ.

The CA/CS terminals may be coupled to a command and address bus to receive commands and addresses (CA) and a chip select (CS) signal. The CA/CS terminals may be supplied with one or more memory addresses. The memory addresses are transferred to an address decoder 112 via a command/address input circuit 105. The address decoder 112 supplies one or more decoded row addresses XADD and one or more decoded column addresses YADD to a row decoder 140 and a column decoder 145, respectively.

The CA/CS terminals may be supplied with one or more commands. The commands are provided as internal command signals to a command decoder 115 via the command/address input circuit 105. The commands may include a read command and/or a write command. The command decoder 115 may include one or more circuits to decode the internal command signals to generate various internal signals and commands for performing operations of various internal circuits. For example, the command decoder 115 may provide a row command signal ACT to the row decoder 140 to select a word line among the plurality of word lines WL and a column command signal R/W to the column decoder 145 to select a bit line among the plurality of bit lines BL.

When a read command as well as a row address and a column address are received by the command decoder 115, data (or read data) are read from the memory cell in the memory array 150 designated by the row and column addresses. The read data are output from the data terminal DQ via a read/write amplifier 155 and an input/output circuit 160. The read/write amplifier 155 may include a plurality of read/write amplifiers corresponding to the memory banks of the memory array 150.

When a write command as well as a row address and a column address are received by the command decoder 115, data (or write data) supplied from the data terminal DQ and transferred via the input/output circuit 160 and the read/write amplifier 155 are written to the memory cell in the memory array 150 designated by the row and column addresses. A data mask may be provided to the data terminal DM to mask portions of the data when written to the memory cell.

The clock terminals CK and/CK may be supplied with external clocks, which are then provided to a clock (CLK) input circuit 120. The clock input circuit 120 may be an input buffer. The external clocks may be complementary. The clock input circuit 120 generates one or more internal clocks ICLK, which are then provided to the command decoder 115 and also to an internal clock generator 130. The internal clock generator 130 provides various internal clocks LCLK based on the ICLK clocks. The LCLK clocks may be used for timing the operations of various internal circuits. For example, the LCLK clocks may be provided to the input/output circuit 160 to perform the operation of provision and receipt of data via the data terminal DQ in a timely manner.

The power supply terminals VSS and VDD may be supplied with power supply potentials. The power supply potentials are supplied to an internal voltage generating circuit 170. The internal voltage generating circuit 170 generates various internal reference potentials, such as VPP, VOD, VARY, and VPERI, for supplying various voltages to be used in the apparatus 100. The internal reference potential VPP may be used in the row decoder 140. The internal reference potentials VOD and VARY may be used in the sense amplifiers SAMP in the memory array 150. The internal reference potential VPERI may be used in peripheral circuit blocks. The internal reference potentials are not limited to those described herein and may include other potentials as appropriate. The internal voltage generating circuit 170 may also be referred to as an internal voltage generator.

The internal voltage generating circuit 170 includes a plurality of resistors 104. The internal voltage generating circuit 170 may include a voltage dividing circuit. The voltage dividing circuit is configured to provide the various internal reference potentials. The resistors 104 may form the voltage dividing circuit. The resistors 104 may be the same resistors with each other. Each of the resistors 104 may be an N+resistor or an N− resistor. The total resistance value of the resistors 104 may be determined at the time of designing the circuit. The resistors 104 are configured to be selectively switched depending on voltage values to be used by the internal circuits as well as specifications, characteristics, and the like of the semiconductor device or the apparatus 100. The voltage dividing circuit may also be referred to as a resistor divider or a potential divider.

The internal voltage generating circuit 170 further includes a plurality of selector switches 106. The selector switches 106 may be provided corresponding to the respective resistors 104. The selector switches 106 may be configured to selectively switch the resistors 104. The selector switches 106 may be configured to be selectively controlled to switch the resistors 104. Each of the selector switches 106 may include, for example, one or more transfer gates. The resistors 104 together with the selector switches 106 may form the voltage dividing circuit.

The internal voltage generating circuit 170 further includes a plurality of amplifiers 102 and a plurality of wiring tracks 108. The selector switches 106 are coupled to the plurality of amplifiers 102 via the plurality of wiring tracks 108. The plurality of wiring tracks 108 may include two wiring tracks. In another embodiment, the amplifiers 102 and the wiring tracks 108 may not be part of the internal voltage generating circuit 170. For example, the amplifiers 102 and the wiring tracks 108 may be provided outside the internal voltage generating circuit 170 and electrically connected or coupled to the selector switches 106 and/or the resistors 104.

The power supply terminals VDDQ and VSSQ may also be supplied with power supply potentials. The power supply potentials are supplied to the input/output circuit 160. The power supply potentials supplied to the power supply terminals VDDQ and VSSQ may be the same potentials as the power supply potentials supplied to the power supply terminals VDD and VSS. The power supply potentials supplied to the power supply terminals VDDQ and VSSQ may be different potentials from the power supply potentials supplied to the power supply terminals VDD and VSS.

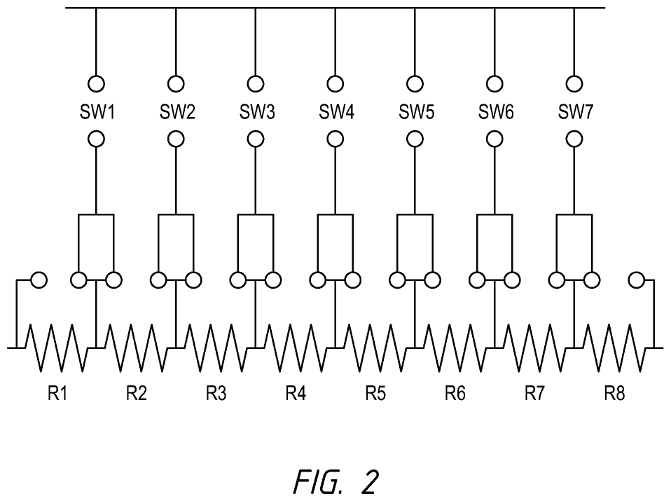

FIG. 2 depicts an example of an equivalent circuit of resistors R1-R8 and selector switches SW1-SW7 of a voltage dividing circuit according to an embodiment of the disclosure. The resistors R1-R8 and the selector switches SW1-SW7 may be, respectively, the resistors 104 and the selector switches 106 of the voltage dividing circuit of the internal voltage generating circuit 170 of FIG. 1. In the example, the resistors R1-R8 are connected in series with one another, and the selector switches SW1-SW7 are coupled to the corresponding resistors R1-R8. Some other switches or selector switches may be connected or coupled to the resistors R1-R8. Poles of the selector switches SW1-SW7 are connected to connecting points between the respective resistors R1-R8, and other poles of the selector switches SW1-SW7 are coupled to the amplifiers 102. In the case where the switches SW1-SW7 include transistors, the electrodes of the transistors may be coupled to wirings, such as the wiring tracks 108, which is coupled to the amplifiers 102. The number of the resistors and selector switches is not limited to the present embodiment and example.

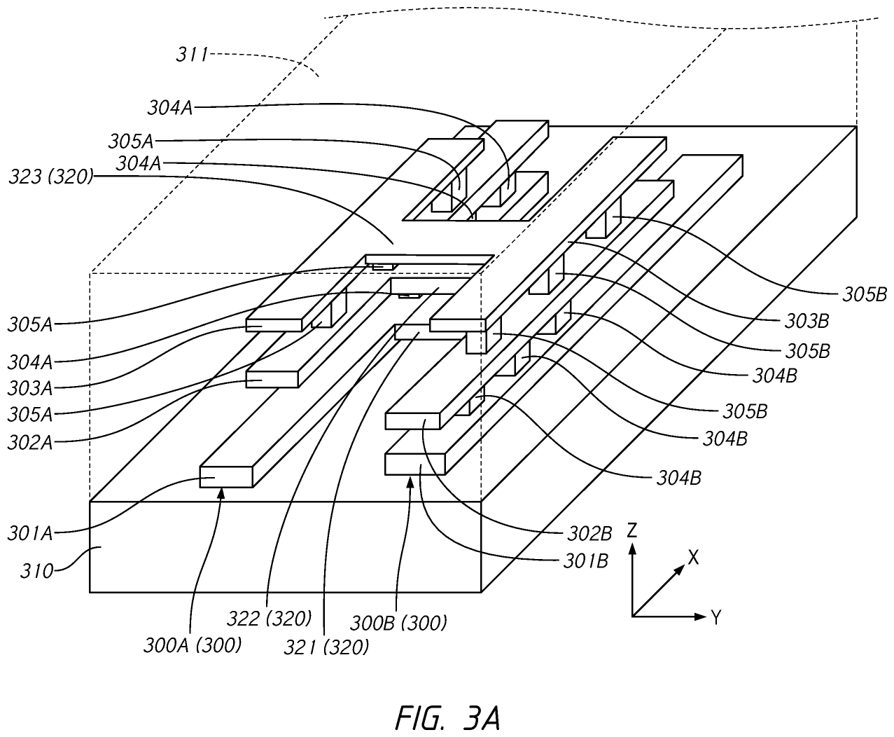

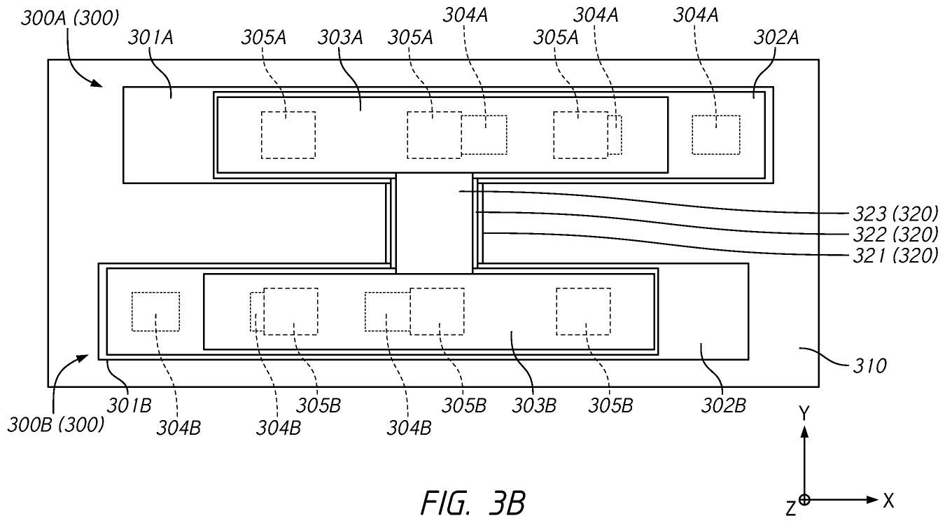

FIGS. 3A and 3B depict an example of a schematic configuration of a plurality of resistor units 300 included in a voltage dividing circuit in a perspective view and a plan view, respectively, according to an embodiment of the disclosure. The voltage dividing circuit may be including in an internal voltage generating circuit. The internal voltage generating circuit may be the internal voltage generating circuit 170 of FIG. 1. The voltage dividing circuit may be the one included in the internal voltage generating circuit 170. Each of the resistor units 300 may correspond to each of the resistors 104 of FIG. 1. Each of the resistor units 300 may correspond to each of the resistors R1-R8 of FIG. 2. The example shows two resistor units (which are herein referred to as first and second resistor units) 300A and 300B as the resistor units 300. The number of the resistor units 300 are not limited to the present embodiment and example.

The first resistor unit 300A includes a resistor layer 301A, a first wiring layer 302A, and a second wiring layer 303A on a semiconductor substrate 310. The resistor layer 301A, the first wiring layer 302A, and the second wiring layer 303A are stacked on top of one another in that order. In the example, the resistor layer 301A is a lowermost layer, the first wiring layer 302A is a middle layer, and the second wiring layer 303A is an uppermost layer. The resistor layer 301A may include a conductive material, such as tungsten (W). The first wiring layer 302A may include a conductive material, such as tungsten (W). The second wiring layer 303A may include a conductive material different from the first wiring layer 302A, such as cupper (Cu). Within the stacked layer configuration on the semiconductor substrate 310, the resistor layer 301A may be a metal layer and referred to as Metal 0 or M0. The second wiring layer 303A may also be a metal layer and referred to as Metal 1 or M1.

In the drawings, for ease of description, one horizontal direction or an X direction, another horizontal direction or a Y direction, and a vertical direction or a Z direction perpendicular to one another in horizontal and vertical planes are defined. The resistor layer 301A, the first wiring layer 302A, and the second wiring layer 303A extend in the X direction. The resistor layer 301A, the first wiring layer 302A, and the second wiring layer 303A overlap or substantially overlap each other in a plan view, that is, when viewed from above in the Z direction. The resistor layer 301A and the first wiring layer 302A have portions overlapping or substantially overlapping with each other in a plan view. The first wiring layer 302A and the second wiring layer 303A have portions overlapping or substantially overlapping with each other in a plan view. Each of the layers 301A, 302A, and 303A may have a length in the X direction and a width in the Z direction determined or designed, for example, depending on specifications, characteristics, or the like of the first resistor unit 300A as part of the voltage dividing circuit.

In the example, the resistor layer 301A may provide at least one resistor or at least one resistor element. The resistor or the resistor element may correspond to at least one of the resistors 104. The resistor or the resistor element may correspond to at least one of the resistors R1-R8. Each of the first wiring layer 302A and the second wiring layer 303A may provide at least one wiring or at least one wiring element. In another example or embodiment, the resistor or the resistor element may be provided by other layers. The other layers may be, for example, the first wiring layer 302A and/or the second wiring layer 303A. The other layers may be, for example, additional layers stacked above or under at least one of the layers 301A, 302A, and 303A on the semiconductor substrate 310. For example, a polyimide layer may be provided and configured to provide the resistor or the resistor element. If one of the layers is designed and configured to be the resistor layer, the rest of the stacked layers may be designed and configured to be the wiring layers.

The first resistor unit 300A further includes a plurality of first contacts 304A and a plurality of second contacts 305A. The first contacts 304A are provided between the resistor layer 301A and the first wiring layer 302A. The first contacts 304A are arranged next to one another with respective spaces therebetween in the X direction. The first contacts 304A may be equally spaced in the X direction. The second contacts 305A are provided between the first wiring layer 302A and the second wiring layer 303A. The second contacts 305A are arranged next to one another with respective spaces therebetween in the X direction. The second contacts 305A may be equally spaced in the X direction. The first contacts 304A and the second contacts 305A provide electrical connection or coupling between the respective layers 301A, 302A, and 303A in the Z direction. The first contacts 304A and the second contacts 305A may include conductive materials, such as cupper (Cu). The first contacts 304A and the second contacts 305A may be contact plugs. When viewed from the above in the Z direction, a group of the first contacts 304A is offset from a group of the second contacts 305A in the X direction. While the example shows three first contacts 304A and three second contacts 305A, the number of each of the first and second contacts 304A and 305A is not limited thereto.

The second resistor unit 300B has the same or substantially the same configuration as the first resistor unit 300A. The second resistor unit 300B includes a resistor layer 301B, a first wiring layer 302B, a second wiring layer 303B, first contacts 304B, and second contacts 305B, which correspond to the resistor layer 301A, the first wiring layer 302A, the second wiring layer 303A, the first contacts 304A, and the second contacts 305A, respectively. Detailed descriptions of these components of the second resistor unit 300B are omitted herein. Each of the layers 301B, 302B. and 303B may have the same or substantially the same length in the X direction as each of the layers 301A, 302A, and 303A. Each of the layers 301B, 302B, and 303B may have the same or substantially the same width in the Z direction as each of the layers 301A, 302A, and 303A. In another example or another embodiment, these lengths and widths may be different between the first and second resistor units 300A and 300B, for example, depending on specifications, characteristics, or the like of the first and second resistor units 300A and 300B as part of the voltage dividing circuit. The resistor layers, the wiring layers, and the contacts of the resistor units 300 may be collectively referred to as resistor layers 301, wiring layers 302 and 303, and contacts 304 and 305, respectively, herein.

In the example, the group of the first contacts 304A of the first resistor unit 300A is arranged in one side of the space between the resistor layer 301A and the first wiring layer 302A in the X direction (for example, +X direction). The group of the first contacts 304B of the second resistor unit 300B is shifted to another side of the space between the resistor layer 301B and the first wiring layer 302B in the opposite X direction (for example, −X direction) when compared with the first contacts 304A of the first resistor unit 300A.

In the example, the second contacts 305A of the first resistor unit 300A and the second contact 305B of the second resistor unit 300B are aligned with each other in the X direction. At least, the middle second contact 305A among the three second contacts 305A and the middle second contact 305B among the three second contacts 305B are aligned with each other. The middle second contacts 305A and 305B are positioned at middle portions of the second wiring layers 303A and 303B in the X direction, respectively.

All of the resistor layer 301A and 301B, the first wiring layers 302A and 302B, the second wiring layers 303A and 303B, the first contacts 304A and 304B, and the second contacts 305A and 305B of the first and second resistor units 300A and 300B may be embedded, for example, in an insulating layer 311. The insulating layer 311 is provided on the semiconductor substrate 310. The insulating layer 311 surrounds the first and second resistor units 300A and 300B on the semiconductor substrate 310. The insulating layer 311 may by formed on the semiconductor substrate 310 by conventional methods and techniques, such as deposition, etching and others as appropriate. The insulating layer 311 may include a plurality of insulating layers, which may be provided between the respective layers 301A/301B, 302A/302B, and 303A/303B. For example, there may be a first insulating layer between the semiconductor substrate 310 and the resistor layers 301A and 301B. There may be a second insulating layer between the resistor layers 301A and 301B and the first wiring layers 302A and 302B. There may be a third insulating layer between the first wiring layers 302A and 302B and the second wiring layers 303A and 303B. There may be a fourth insulating layer above the second wiring layers 303A and 303B. Some of the insulating layers may form one insulating layer. The insulating layer 311 may include an insulating material, such as silicon oxide or silicon nitride. The first contacts 304A and 304B and the second contacts 305A and 305B may be contact plugs or contact vias formed in the insulating layer 311. Such contact plugs or contact visas may be formed by conventional methods and techniques, such as deposition, etching, photolithography, polishing and others as appropriate. For the sake of simplification of the drawings, the insulating layer 311 is shown with dotted lines in FIG. 3A and is omitted in FIG. 3B.

The first wiring layers 302A and 302B and the second wiring layers 303A and 303B together with the first contacts 304A and 304B and the second contacts 305A and 305B are configured to electrically connect or couple the resistor layers 301A and 301B and hence the resistors to other circuit elements, such as the selector switches 106 of FIG. 1 or SW1-SW8 of FIG. 2. The first wiring layers 302A and 302B, the second wiring layers 303A and 303B, the first contacts 304A and 304B, and the second contacts 305A and 305B may form connecting terminals or connecting lines of the respective resistors in the resistor layers 301A and 301B to the other circuit elements. The connecting terminals/lines may also electrically connect or couple the respective resistors or resistor elements with each other.

According to the present embodiment, the first resistor unit 300A and the second resistor unit 300B are linked with each other by a bridge 320. The linkage of the two resistor units 300A and 300B by the bridge 320 may be at least electrical. The linkage may also be both physical and electrical. The bridge 320 include a first bridging portion 321, a second bridging portion 322, and a third bridging portion 323.

The first bridging portion 321 is provided in the same layer as the resistor layer 301A of the first resistor unit 300A and the resistor layer 301B of the second resistor unit 300B. The first bridging portion 321 may be part of the resistor layers 301A and 301B. The first bridging portion 321 extends and links between the resistor layers 301A and 301B in the Y direction. One end and another end of the first bridging portion 321 in the Y direction are at middle portions of the resistor layers 301A and 301B, respectively. The middle portion of the resistor layer 301A may be spaced from or positioned at a predetermined distance from end portions of the resistor layer 301A in the X direction. The middle portion of the resistor layer 301A may be at or around a lengthwise center of the resistor layer 301A in the X direction. The middle portion of the resistor layer 301B may be spaced from or positioned at a predetermined distance from end portions of the resistor layer 301B in the X direction. The middle portion of the resistor layer 301B may be at or around a lengthwise center of the resistor layer 301B in the X direction. In the example, the first bridging portion 321 is a lowermost bridging layer of the bridge 320. The first bridging portion 321 may be formed at the same time as the resistor layers 301A and 301B as one patterned layer over the semiconductor substrate 310 by conventional methods and techniques, such as deposition, etching, photolithography and others as appropriate, during processing or manufacturing of the semiconductor device or the apparatus 100, such as a memory device.

The second bridging portion 322 is provided in the same layer as the first wiring layer 302A of the first resistor unit 300A and the first wiring layer 302B of the second resistor unit 300B. The second bridging portion 322 may be part of the first wiring layers 302A and 302B. The second bridging portion 322 extends and links between the first wiring layers 302A and 302B in the Y direction. One end and another end of the second bridging portion 322 in the Y direction are at middle portions of the first wiring layers 302A and 302B, respectively. The middle portion of the first wiring layer 302A may be spaced from or positioned at a predetermined distance from end portions of the first wiring layer 302A in the X direction. The middle portion of the first wiring layer 302B may be spaced from or positioned at a predetermined distance from end portions of the first wiring layer 302B in the X direction. In the example, unlike the middle portion of the resistor layer 301A, since the first wiring layer 302A is arranged offset to one side in the lengthwise direction that is the X direction, the middle portion of the first wiring layer 302A may not be at or around a lengthwise center of the first wiring layer 302A in the X direction. Also, unlike the middle portion of the resistor layer 301B, since the first wiring layer 302B is arranged offset to one side in the lengthwise direction that is the X direction, the middle portion of the first wiring layer 302B may not be at or around a lengthwise center of the first wiring layer 302B in the X direction. In another example or embodiment, the first wiring layers 302A and 302B may be arranged and positioned in a similar manner to the resistor layers 301A and 301B, and in such a case, the middle portions of the first wiring layers 302A and 302B may be at or around a lengthwise center thereof in the X direction. In the present example, the second bridging portion 322 is a middle bridging layer of the bridge 320. The second bridging portion 322 may be formed at the same time as the first wiring layers 302A and 302B as one patterned layer above the resistor layers 301A and 301B by conventional methods and techniques, such as deposition, etching, photolithography and others as appropriate, during processing or manufacturing of the semiconductor device or the apparatus 100.

The third bridging portion 323 is provided in the same layer as the second wiring layer 303A of the first resistor unit 300A and the second wiring layer 303B of the second resistor unit 300B. The third bridging portion 323 may be part of the second wiring layers 303A and 303B. The third bridging portion 323 extends and links between the second wiring layers 303A and 303B in the Y direction. One end and another end of the third bridging portion 323 in the Y direction are at middle portions of the 303A and 303B, respectively. The middle portion of the second wiring layer 303A may be spaced from or positioned at a predetermined distance from end portions of the second wiring layer 303A in the X direction. The middle portion of the second wiring layer 303A may be at or around a lengthwise center of the second wiring layer 303A in the X direction. The middle portion of the second wiring layer 303B may be spaced from or positioned at a predetermined distance from end portions of the second wiring layer 303B in the X direction. The middle portion of the second wiring layer 303B may be at or around a lengthwise center of the second wiring layer 303B in the X direction. In the example, the third bridging portion 323 is an uppermost bridging layer of the bridge 320. The third bridging portion 323 may be formed at the same time as the second wiring layers 303A and 303B as one patterned layer above the first wiring layers 302A and 302B by conventional methods and techniques, such as deposition, etching, photolithography and others as appropriate, during processing or manufacturing of the semiconductor device or the apparatus 100.

The third bridging portion 323 is aligned with the corresponding ones of the second contacts 305A and 305B in a plan view. In the example, the third bridging portion 323 is arranged at a position corresponding to the middle ones of the second contacts 305A and 305B. Both ends of the third bridging portion 323 in the Y direction are in alignment with the corresponding middle second contacts 305A and 305B in the X direction, respectively. The third bridging portion 323 in the uppermost layer of the bridge 320 as part of the second wiring layers 303A and 303B forms a conductive path with the second contacts 305A and 305B.

The second bridging portion 322 is aligned with the third bridging portion 323 in a plan view. The second bridging portion 322 has at least an overlapping or a substantially overlapping portion with the third bridging portion 323 when viewed from the above in the Z direction. Both ends of the second bridging portion 322 in the Y direction are in alignment with the middle second contacts 305A and 305B in the X direction, respectively. The second bridging portion 322 in the middle layer of the bridge 300 as part of the first wiring layers 302A and 302B forms a conductive path with the second contacts 305A and 305B.

The first bridging portion 321 is aligned with both the second bridging portion 322 and the third bridging portion 323 in a plan view. The first bridging portion 321 has at least an overlapping or a substantially overlapping portion with both the second bridging portion 322 and the third bridging portion 323 when viewed from the above in the Z direction. Although the first bridging portion 321 is positioned multiple layers below the second contacts 305A and 305B, both ends of the first bridging portion 321 in the Y direction are in alignment with the middle second contacts 305A and 305B in the X direction, respectively, and while being part of the resistor layers 301A and 301B, forms a conductive path with the second contacts 305A and 305B through the first contacts 304A and 304B and the first wiring layers 302A and 302B.

The bridge 320 including the first, second, and third bridging portions 321, 322, and 323 electrically connects or couples the first resistor unit 300A and the second resistor unit 300B with each other via the respective layers and contacts. The bridge 320 may form part of the connecting terminals or connecting lines of the respective resistors in the resistor layers 301A and 301B to the other circuit elements, such as the selector switches, and/or the neighboring resistors. Hence, the connecting terminals include the first wiring layers 302A and 302B, the second wiring layers 303A and 303B, the first contacts 304A and 304B, the second contacts 305A and 305B, and the bridge 320.

According to the present embodiments, the total resistance value of the connecting terminals may be less than that of the resistor layers 301 or the resistors of the resistor layers 301.

In a case where a greater number of the contacts 304 and 305 are provided between the respective layers 301, 302, and 303, and even if resistances of the contacts 304 and 305 fluctuate due to process variations, the resistance fluctuation may not affect the resistance between the resistors of the resistor layers 301. This may eliminate or mitigate an offset between the actual resistance values and the simulated or designed resistance values. Even if there is such an offset, the offset may not be substantive for the operation of the voltage dividing circuit of the internal voltage generating circuit or may be within the anticipated range of offset compensation or adjustment.

There may be less differences in resistance value among the wirings, the contacts, and the bridge of the connecting terminals. Even if there are such resistance value differences, the differences may be negligible or not substantive for the operation of the voltage dividing circuit of the internal voltage generating circuit.

Since the resistor units 300 can be arranged relatively closer to each other by the bridge 320 linking the two resistor units 300 at the middle portions thereof (in one example, at the positions corresponding to the middle second contacts 305 in a plan view), the total distance of the electric path between the two resistor units 300 may be made relatively shorter. This may reduce the total resistance value without reducing the number of the contacts 304 and 305.

The total resistance value from the resistor layers 301 to the second wiring layers 303 through the first wiring layers 302 and the contacts 304 and 305 may not significantly increase from the total resistance value of a case where there is only the resistor layers 301 on the semiconductor substrate 310. This indicates there is a less impact on the total resistance value within each of the resistor units 300 having the multiple conductive layers and contacts.

Even if process parameters, such as a wiring sheet resistance and a contact resistance, of the connecting terminals fluctuate due to process variations, the parameter fluctuation may not affect the resistance values between the resistors or the resistor elements.

The voltage dividing circuit including the resistor units 300 of the present embodiment have the connecting terminals with relatively lower resistance values and relatively less varied resistance values and hence achieves speedy reference potential/voltage setting without a significant or non-negligible delay. This makes the voltage dividing circuit of the present embodiment further suitable, for example, in a case where setting of internal reference potentials or voltages is performed in a high-speed operation mode.

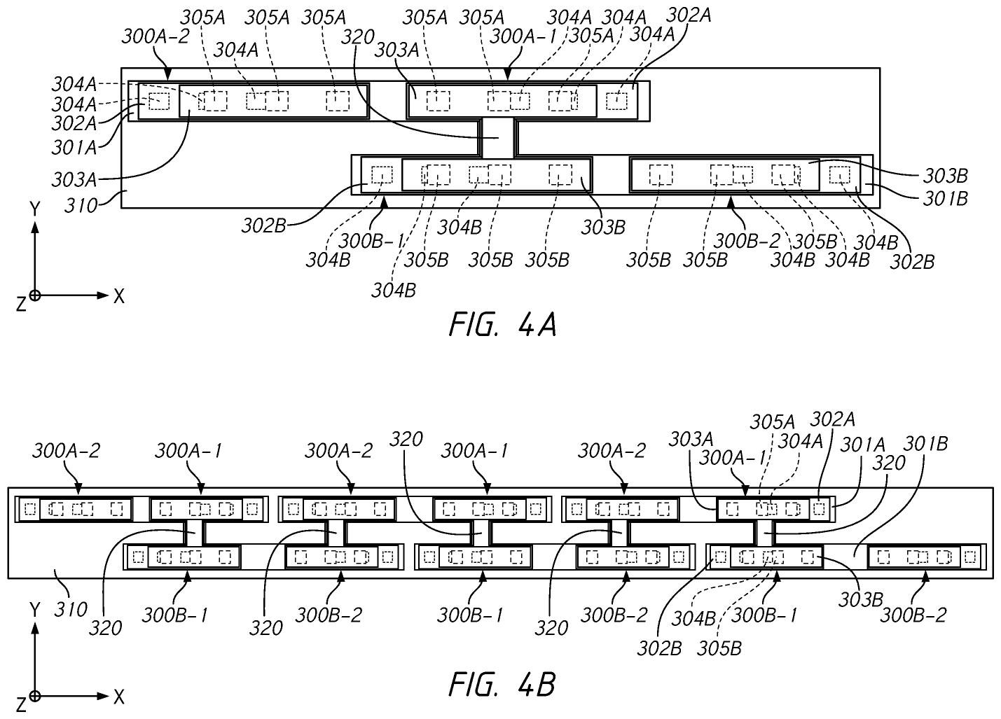

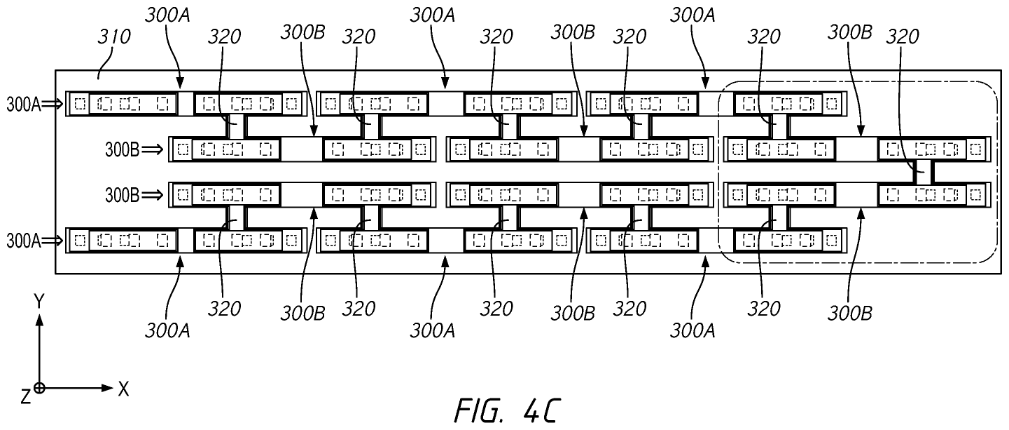

FIGS. 4A, 4B, and 4C depict examples of a schematic configuration of a plurality of resistor units in a voltage dividing circuit in a plan view according to an embodiment of the disclosure. As shown in FIGS. 4A, 4B, and 4C, the voltage dividing circuit may include more than two resistor units 300 of FIGS. 3A and 3B.

In the example of FIG. 4A, the first resistor unit 300A includes two resistor units (or resistor subunits) 300A-1 and 300A-2 arranged next to each other in the X direction in a plan view, and the second resistor unit 300B includes two resistor units (or resistor subunits) 300B-1 and 300B-2 arranged next to each other in the X direction Each of the resistor subunits 300A-1, 300A-2, 300B-1, and 300B-2 has the same or the substantially the same configuration as the first and second resistor units 300A and 300B, except that the resistor layers 301A and 301B are extended in the X direction to have the respective wiring layers 302A, 302B, 303A, and 303B and contacts 304A, 304B, 305A, 305B arranged over the extended strips of the respective resistor layers 301A and 301B. Also, on the resistor layer 301A, the rest of the components of the resistor subunits 300A-1 and 300A-2 are arranged in a symmetrical manner. Likewise, on the resistor layer 301B, the rest of the components of the resistor subunits 300B-1 and 300B-2 are arranged in a symmetrical manner. The resistor subunit 300A-1 of the first resistor unit 300A and the resistor subunit 300B-1 of the second resistor unit 300B are parallel to each other in the Y direction and electrically connected or coupled to each other by one bridge 320 at the middle portions thereof. The resistor subunit 300A-1 is also electrically connected or coupled to the resistor subunit 300A-2 through the common resistor layer 301A. The resistor subunit 300B-1 is also electrically connected or coupled to the resistor subunit 300B-2 through the common resistor layer 301B. Therefore, there is an electrical path or a conductive path running from the first resistor unit 300A to the second resistor unit 300B with the respective layers and contacts and the bridge 320.

As shown in the examples of FIGS. 4B and 4C, this configuration may be expanded as much as allowed within the specifications, designs, or the like of the voltage dividing circuit and/or the internal voltage generating circuit. The first and second resistor units 300A and 300B including the bridge 320 of FIG. 4A may form a pair of resistor units or may be grouped as one linked or bridged unit, and a plurality of unit pairs or linked/bridged units may be arranged in an appropriate manner within a designated circuit area on the semiconductor substrate 310. In the example of FIG. 4B, a first unit pair is provided at a leftmost position in the designated circuit area, and a second unit pair is shifted rightward from the first unit pair in the X-direction such that the resistor unit 300B-2 of the first unit pair faces the 300A-2 of the second unit pair in the Y-direction. In a similar manner, the third pair unit is provided at a rightmost position shifted rightward from the second or middle pair unit in the X-direction. To link these unit pairs, additional bridges 320 are provided between the facing resistor subunits, for example between the resistor subunit 300B-2 of the first, leftmost unit pair and the resistor subunit 300A-2 of the second, middle unit pair and between the resistor subunit 300B-2 of the middle unit pair and the resistor subunit 300A-2 of the third, rightmost unit pair. Also, in each of the unit pair, the resistor subunits 300A-1, 300A-2, 300B-1, and 300B-2 may be adjusted in terms of position, size, and the like. For instance, the resistor subunits 300A-1 and 300A-2 are further spaced from each other while the resistor layer 301A is further extended in the X direction, compared to those in the example of FIG. 4A. Similarly, the resistor subunits 300B-1 and 300B-2 within one resistor unit 300B are further spaced from each other while the resistor layer 301B is further extended in the X direction, compared to those in the example of FIG. 4A. In the example, the unit pairs have the same configuration with one another. In other words, once one unit pair is determined and designed, multiple unit pairs may be simply arranged in a designated circuit area with the bridges 320 linking the respective unit pairs.

In the example of FIG. 4C, the resistor units 300 linked via the bridges 320 to one another in the FIG. 4B are treated as one resistor unit layout, and two of such resistor unit layout are arranged next to each other in a symmetrical manner within the larger designated circuit area. The example also illustrates that the first and second resistor units 300A and 300B form one or more lines of the resistor units 300 in the X direction. The lines run in one direction (for example, +X direction) and turn around in another direction (for example, −X direction) within a designated circuit area on the semiconductor substrate 310. This arrangement of the resistor unit lines running back and forth substantially and efficiently fills the designated circuit area in a plan view. Also, there may be no substantive difference in the total resistance value between the turnaround area (indicated with the dot-dashed line in the drawing) and other areas within the designated circuit area since the resistor units and hence the thus-formed lines have substantially the same configuration with one another. Even if there is a difference, it may be negligible in terms of operation, performance, and the like of the voltage dividing circuit of the voltage generating circuit. No fluctuation or a non-substantive fluctuation in the total resistance value among the various areas leads to further stable operation of the resistor units 300 and the voltage dividing circuit. This also enables the arrangement of the resistor units 300 in a further denser manner without affecting the operation stability. The degree of the circuit design hence increases. For instance, the number of the contacts between the respective layers can be changed without significantly affecting the resistance values within the designated circuit area.

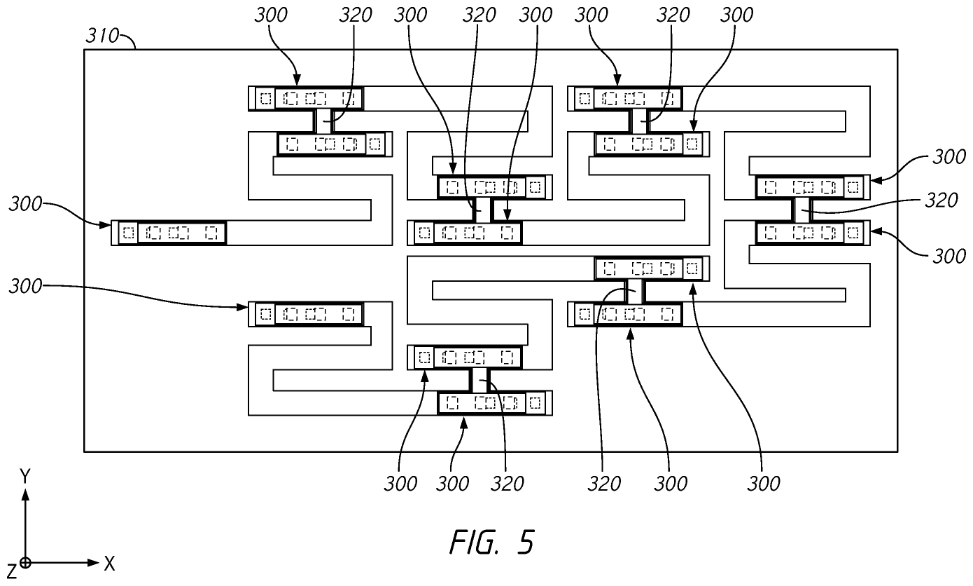

FIG. 5 depicts still another example of a schematic configuration of a plurality of resistor units in a voltage dividing circuit in a plan view according to an embodiment of the disclosure. As shown in the example of FIG. 5, the greater number of the resistor units 300 can be provided in various arrangements that form multiples lines and/or patterns extending, running, and turning in multiple directions. Even in such a further advanced or elaborated layout, the resistor units 300 have the same or substantially the same configuration with one another and can be properly arranged at designated positions, further effectively filling the designated circuit area on the semiconductor substrate 310. All the advantages and effects according to the embodiments and the examples described herein can be achieved by this layout.

Accordingly, various arrangements and layouts are possible based on the configuration of the resistor unit 300 including the bridge 320 shown in FIGS. 3A and 3B with simple adjustments as needed. The configuration of the resistor unit 300 achieves the significantly greater degree of the circuit design.

In the present embodiments and examples, as shown in FIG. 3A, each of the resistor units 300 includes the two wiring layers 302 and 303 on top of the resist layer 301, forming the three-layered configuration. The number of the layers and/or the wiring layers is not limited to the present embodiments and examples. In one instance, there may be three or more wiring layers stacked on the resist layer 301, making the layer configuration four or more layered. In another instance, there may be one resist layer and one wiring layer stacked on and coupled to each other as a two-layered configuration. In any instances, in a similar manner to the present embodiments and examples, the layers in each resistor unit 300 may be coupled to one aother via contacts in the vertical direction, and a bridge configuration may be provided between the layers of the neighboring resistor units 300 in the horizontal direction. The same or substantially the same advantages and effects as the present embodiments and examples may be achieved.

The plurality of resistor units 300 described herein may be included in a voltage dividing circuit. The voltage dividing circuit may be included in an internal voltage generating circuit. An internal voltage generating circuit may be included in a memory device. A memory device may be one example of a semiconductor device. A semiconductor device and/or a memory device may be one example of the apparatus 100. One example of a memory device is a dynamic random access memory (DRAM). The embodiments and the examples of the disclosure are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, may also be applicable. Other examples of the semiconductor device, such as logic ICs (a microprocessor, an application-specific integrated circuit (ASIC) or the like), may also be applicable.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising a voltage dividing circuit including:
a first resistor unit;
a second resistor unit parallel to the first resistor unit in a first direction; and
a bridge between the first resistor unit and the second resistor unit and configured to link a first middle portion of the first resistor unit to a second middle portion of the second resistor unit, the first and second middle portions being middle portions of the first and the second resistor units in a second direction perpendicular to the first direction.

2. The apparatus according to claim 1, wherein the first and second middle portions of the first and the second resistor units are spaced from end portions of the first and second resistor units in the second direction.

3. The apparatus according to claim 1, wherein the first and second middle portions of the first and the second resistor units are at or around lengthwise centers of the first and second resistor units in the second direction.

4. The apparatus according to claim 1, wherein each of the first and second resistor units includes:
at least a first layer and a second layer on a semiconductor substrate, the first layer including a resistor, and the second layer including a wiring; and
a plurality of contacts between the first layer and the second layer.

5. The apparatus according to claim 4, wherein the first and second middle portions linked by the bridge are middle portions of at least the second layers of the first and second resistor units.

6. The apparatus according to claim 4, wherein in each of the first and second resistor units, at least one of the plurality of contacts is at a middle portion of the second layer.

7. The apparatus according to claim 4, wherein in each of the first and second resistor units, the bridge is positioned corresponding to at least one of the contacts at a middle portion of the second layer.

8. The apparatus according to claim 4, wherein the bridge includes:
a first bridging portion between the first layers of the first and second resistor units; and
a second bridging portion between the second layers of the first and second resistor units.

9. The apparatus according to claim 7, wherein the first bridging portion and the second bridging portion have portions overlapping with each other in a plan view.

10. The apparatus according to claim 1, wherein the voltage dividing circuit includes a plurality of selector switches configured to selectively switch the first and second resistor units, and the first and second resistor units provide a plurality of internal reference potentials.

11. The apparatus according to claim 1, wherein the first and second resistor units form a pair, and the voltage dividing circuit includes more than two pairs.

12. The apparatus according to claim 1, further comprising an internal voltage generating circuit, wherein the internal voltage generating circuit including the voltage dividing circuit.

13. The apparatus according to claim 1, wherein the apparatus includes a memory device, and the voltage dividing circuit provides a plurality of internal reference potentials for a plurality of circuit elements of the memory device.

14. An apparatus, comprising, a voltage dividing circuit including:
a first resistor unit and a second resistor unit, each including a resistor layer and a wiring layer on a semiconductor substrate, the second resistor unit parallel to the first resistor unit in a first direction in a plan view; and
a bridge configured to link the first resistor unit to the second resistor unit, wherein the wiring layer of each of the first and second resistor units includes a middle portion at a predetermined distance from end portions of the wiring layer in a second direction perpendicular to the first direction, and
the bridge links the middle portions of the wiring layers of the first and second resistor units.

15. The apparatus according to claim 14, wherein the middle portion of each of the first and the second resistor units is at or around a lengthwise center of each of the wiring layer in the second direction.

16. The apparatus according to claim 14, wherein
each of the first and second resistor units further includes a plurality of contacts between the resistor layer and the wiring layer, the plurality of contacts include a middle contact at the middle portion of the wiring layer, and
the bridge links the middle contacts of the first and second resistor units with each other.

17. The apparatus according to claim 14, wherein the voltage dividing circuit further includes a plurality of selector switches, and the wiring layers of the first and second resistor units are electrically coupled to the selector switches.

18. The apparatus according to claim 14, further comprising an internal voltage generating circuit, wherein the internal voltage generating circuit including the voltage dividing circuit.

19. An internal voltage generating circuit of a semiconductor device, comprising a voltage dividing circuit, the voltage dividing circuit including:
a plurality of selector switches; and
a plurality of resistor units paired with the plurality of selector switches, the plurality of resistor units including a first resistor unit and a second resistor unit, the second resistor unit parallel to the first resistor unit in a first direction in a plan view; and
a bridge configured to link the first resistor unit to the second resistor unit, wherein
each of the first and second resistor units include a resistor layer and a wiring layer on a semiconductor substrate,
the wiring layer of each of the first and second resistor units includes a middle portion at a predetermined distance from end portions of the wiring layer in a second direction perpendicular to the first direction, and
the bridge links the middle portions of the wiring layers of the first and second resistor units.

20. The internal voltage generating circuit according to claim 19, wherein the semiconductor device is a memory device.
